(19) United States
(12) Patent Application Publication
(10) Pub. No.: US 2013/0000702 A1
(43) Pub. Date: Jan. 3, 2013

(54) PHOTOVOLTAIC DEVICE WITH RESISTIVE CIGS LAYER AT THE BACK CONTACT

(75) Inventors: Korhan Demirkan, Santa Clara, CA (US); Jochen Titus, Sunnyvale, CA (US); Robert Tas, Aromas, CA (US)

(73) Assignee: MiaSole, Santa Clara, CA (US)

(21) Appl. No.: 13/173,407

(22) Filed: Jun. 30, 2011

(51) Int. Cl. H01L 31/02; H01L 31/18

(52) U.S. Cl. 136/252; 438/73; 257/E31.001

(57) ABSTRACT

A photovoltaic device including a substrate, a first electrode layer over the substrate and a resistive p-type semiconductor layer over the first electrode layer. The device also includes a p-type absorber layer over the resistive p-type semiconductor layer, an n-type semiconductor layer over the p-type absorber layer and a second electrode layer over the n-type semiconductor layer. Additionally, a resistivity of the resistive p-type semiconductor layer is greater than a resistivity of the p-type absorber layer.

### FIELD

The present invention is directed to photovoltaic devices, in particular to thin film solar cells with a resistive CIGS layer at the back contact.

### BACKGROUND

Copper indium diselenide (CuInSe₂, or CIS) and its higher band gap variants copper indium gallium diselenide (Cu(In,Ga)Se₂, or CIGS), copper indium aluminum diselenide (Cu(In,Al)Se₂), copper indium gallium aluminum diselenide (Cu(In,Ga,Al)Se₂) and any of these compounds with sulfur replacing some of the selenium represent a group of materials, referred to as copper indium selenide CIS based alloys, have desirable properties for use as the absorber layer in thin-film solar cells. To function as a solar absorber layer, these materials should be p-type semiconductors. This may be accomplished by establishing a slight deficiency in copper, while maintaining a chalcopyrite crystalline structure. In CIGS, gallium usually replaces 20% to 30% of the normal indium content to raise the band gap; however, there are significant and useful variations outside of this range. If gallium is replaced by aluminum, smaller amounts of aluminum are used to achieve the same band gap.

### SUMMARY

An embodiment relates to a photovoltaic device including a substrate, a first electrode layer over the substrate and a resistive p-type semiconductor layer over the first electrode layer. The device also includes a p-type absorber layer over the resistive p-type semiconductor layer, an n-type semiconductor layer over the p-type absorber layer and a second electrode layer over the n-type semiconductor layer. Additionally, a resistivity of the resistive p-type semiconductor layer is greater than a resistivity of the p-type absorber layer.

Another embodiment relates to a photovoltaic device including a substrate, a first electrode layer over the substrate and a p-type absorber layer over the resistive p-type semiconductor layer. The device also includes an n-type semiconductor layer over the p-type absorber layer and a second electrode layer over the n-type semiconductor layer. Additionally, the junction of the p-type absorber layer and the n-type semiconductor layer form a diode and a thickness of the p-type absorber layer is greater than a sum of a depletion width of the diode in the p-type absorber layer and a hole diffusion length in the p-type absorber layer.

Another embodiment relates to a method of making a photovoltaic device. The method includes depositing a first electrode layer over a substrate, depositing a resistive p-type semiconductor layer over the first electrode layer and depositing a p-type absorber layer over the resistive p-type semiconductor layer. The method also includes depositing an n-type semiconductor layer over the p-type absorber layer and depositing a second electrode layer over the n-type semiconductor layer. Additionally, a resistivity of the resistive p-type semiconductor layer is greater than a resistivity of the p-type absorber layer.

Another embodiment relates to a method of operating a photovoltaic device. The device includes a substrate, a first electrode layer over the substrate, a p-type absorber layer over the resistive p-type semiconductor layer, an n-type semiconductor layer over the p-type absorber layer and a second electrode layer over the n-type semiconductor layer. The method includes applying a current or voltage to the first and the second electrode layers such that a junction of the p-type absorber layer and the n-type semiconductor layer form a diode with a depletion region which partially extends from the junction into the p-type absorber layer to a depth which differs from the thickness of the p-type absorber layer by at least a hole diffusion length in the p-type absorber layer.

### BRIEF DESCRIPTION OF THE DRAWINGS

FIG. 1 is a schematic side cross-sectional view of a CIS based solar cell of one embodiment.

FIG. 2 is a schematic side cross-sectional view of a CIS based solar cell of another embodiment.

FIG. 3 illustrates a highly simplified schematic diagram of a top view of a modular sputtering apparatus that can be used to manufacture the solar cell depicted in FIGS. 1 and 2.

### DETAILED DESCRIPTION

U.S. Published Application No. 2005/0109392 A1 (“Hollars”), titled “Manufacture Apparatus and Method for Large-scale production of thin-film solar cells”, which is filed on Oct. 25, 2004 and published on May 26, 2005 incorporated herein by reference in its entirety discloses a vacuum sputtering apparatus which includes an input module for paying out a web substrate material from a roll of the substrate material, a plurality of process modules for receiving the substrate material from the input module, and an output module. The process modules include one or more sputtering targets for sputtering material onto the web substrate. The output module receives the substrate material from the process modules. The web substrate can be heated by radiation heaters to obtain a sufficient process temperature for depositing CIS based layers.

This technique taught by Hollars provides a large-scale manufacturing system for the economical production of thin-film CIS based solar cells with significantly lower cost.

As grown copper indium diselenide based films (e.g. CIGS films) are intrinsically p-type. However, it was found that a small amount of sodium dopants in copper indium diselenide based films (e.g. copper indium gallium diselenide “CIGS” films) increases the p-type conductivity of the copper indium gallium diselenide film and the open circuit voltage, and in turn, improves the efficiency of the solar cell. For example, Ramanathan (Ramanathan et al., Prog. Photovolt. Res. Appl. 11 (2003) 225, incorporated herein by reference in its entirety) teaches that a solar cell, having an efficiency as high as 19.5%, may be obtained by using a soda-lime glass substrate in combination with depositing a copper indium diselenide film under a high growth temperature. This method significantly improves the efficiency of a traditional solar cell by diffusing sodium from the glass substrate into the copper indium diselenide film. However, it is difficult to control the amount of the sodium provided to the copper indium diselenide based film and the speed of the sodium diffusion from a glass substrate. Furthermore, unlike glass substrates, other substrates, such as metal and plastic substrates, do not provide such a readily available supply of sodium.

Rudmann (Rudmann et al., Thin Solid Films 32 (2003) 37) teaches forming a NaF or NaSe layer between the copper indium gallium diselenide layer and a first electrode (also referred as a back electrode). Sodium doping in this system can be controlled by modulating the sodium diffusion from the NaF or NaSe layer into the copper indium gallium diselenide layer. Although the amount of sodium in copper indium gallium diselenide may be more controllable than in the Ramanathan method, the NaF or NaSe interlayer results in a poor adhesion and a greater schottky barrier between the copper indium gallium diselenide layer and the first electrode.

Yun (Yun et al., Thin Solid Films 515 (2007) 5876-5879) teaches DC sputtering a sodium-containing molybdenum layer from a composite Na—Mo target. It has been found that resulting solar cells have an improved efficiency because the sodium incorporation enhances the open circuit voltage and fill factor. However, this method is limited by the property of the Na—Mo target, which has a high propensity to crack.

Use of a resistive transparent conductive oxide (TCO) layer for the top electrode of a photovoltaic device improves the device efficiency by reducing the negative effects of spatial inhomogenous diode systems. In a solar cell under light illumination, the major matrix of the cell generates photo-current. However, any spatially distributed defective regions with lower turn on voltage (lower than the operating voltage) will operate under a forward bias condition (having a current opposite to the overall device). This significantly lowers the open circuit voltage (Voc) and to some extent the fill factor (FF).

The inventors have observed an improvement in cell efficiency with increasing CIGS thickness, even where the total CIGS thickness was exceed the sum of the depletion width and the diffusion length in the CIGS layer. Based on this, the inventors have inferred that the increased CIGS thickness acts as an additional resistive layer that spatially isolates the non-uniform diodes. In theory, the main role of the resistive layer is based on lowering of the voltage to which the diode is exposed and therefore restricting the amount current flow. Therefore, it may not matter if the resistance layer is located above or below the absorber layer.

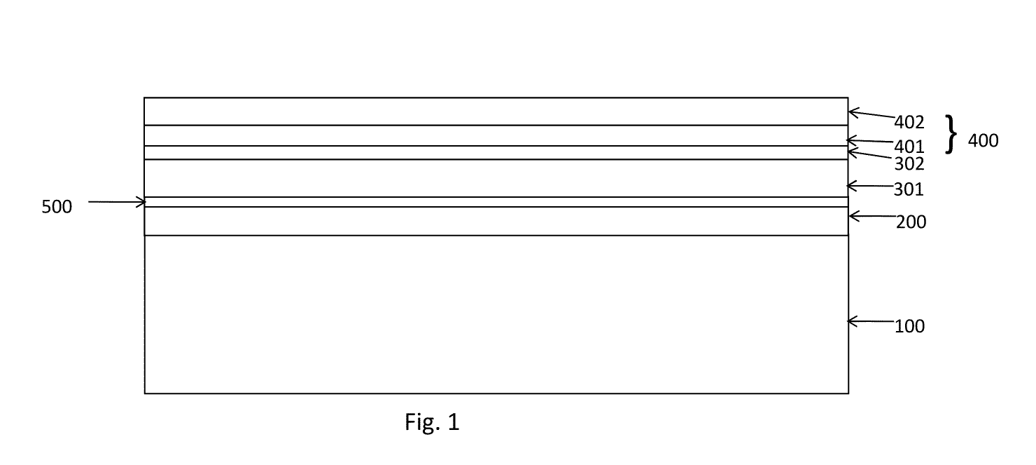

FIG. 1 illustrates a solar cell according to a first embodiment of the invention. In this embodiment, the solar cell contains the substrate 100 and a first (lower) electrode 200. The substrate 100 may be metal (e.g., aluminum or stainless steel), glass or polymer film. The first electrode may comprise a transition metal, for example, one of Mo, W, Ta, V, Ti, Nb, Zr, or alloys thereof. In one embodiment, the step of depositing the first electrode 200 may comprise DC sputtering a first target comprising a transition metal, such as molybdenum. Optionally, the first electrode 200 of the solar cell may comprise one or more barrier layers (not shown) located at the bottom of the electrode 200, and/or one or more adhesion layers (not shown) located on top of the electrode 200. The barrier layer substantially prevents alkali diffusion from the electrode 200 into the substrate 100. The optional barrier layer and adhesion layer may comprise any suitable materials. For example, they may be independently selected from a group consisting Mo, W, Ta, V, Ti, Nb, Zr, Cr, TiN, ZrN, TaN, VN, V₂N or combinations thereof. In one embodiment, while the barrier and adhesion layers may be oxygen and sodium free as deposited, the first electrode 200 may comprise Mo which contains sodium and oxygen and/or be deposited at a higher pressure than the barrier layer to achieve a lower density than the barrier layer. For example, layer 200 may optionally contain 5 to 40 atomic percent oxygen and 0.01 to 1.5 atomic percent sodium. The adhesion layer may optionally contain 1 to 10 atomic percent oxygen or no oxygen and sodium as deposited.

A resistive p-type semiconductor layer 500 is located over the first electrode 200. The resistivity of semiconductor materials may vary widely depending on the amount of doping (e.g., the resistivity of doped semiconductors may vary from approximately 10⁻⁷ to 10² Ω-cm). Thus, the resistive p-type semiconductor layer 500 may comprise a relatively thin layer of high resistivity (intrinsic or low doped) material or a relatively thick layer of a low resistivity (highly doped) material. Alternatively, the resistive p-type semiconductor layer 500 may comprise two or more layers of high resistivity and low resistivity materials. Preferably, the resistance of the resistive p-type semiconductor layer 500 is in the range of 10¹ to 10⁶ ohm-cm. The resistive p-type semiconductor layer 500 may be made of any p-type semiconductor material. In one embodiment, the resistive p-type semiconductor layer 500 comprises CIGS. In another embodiment, resistive p-type semiconductor layer 500 comprises a layer of p-CIGS (e.g., slightly Cu deficient CIGS) on a layer of p-Si (e.g., Si doped with a low concentration of B, e.g. 10¹² to 10¹⁵ cm⁻³ dopant density of B to achieve 10¹ to 10⁴ ohm-cm resistivity.

In still another embodiment, the resistive p-type semiconductor layer 500 comprises p-ZnSe (e.g., ZnSe doped with a low concentration of sodium or nitrogen, e.g. a sufficient concentration to provide a carrier density of 10¹² to 10¹⁶ cm⁻³.

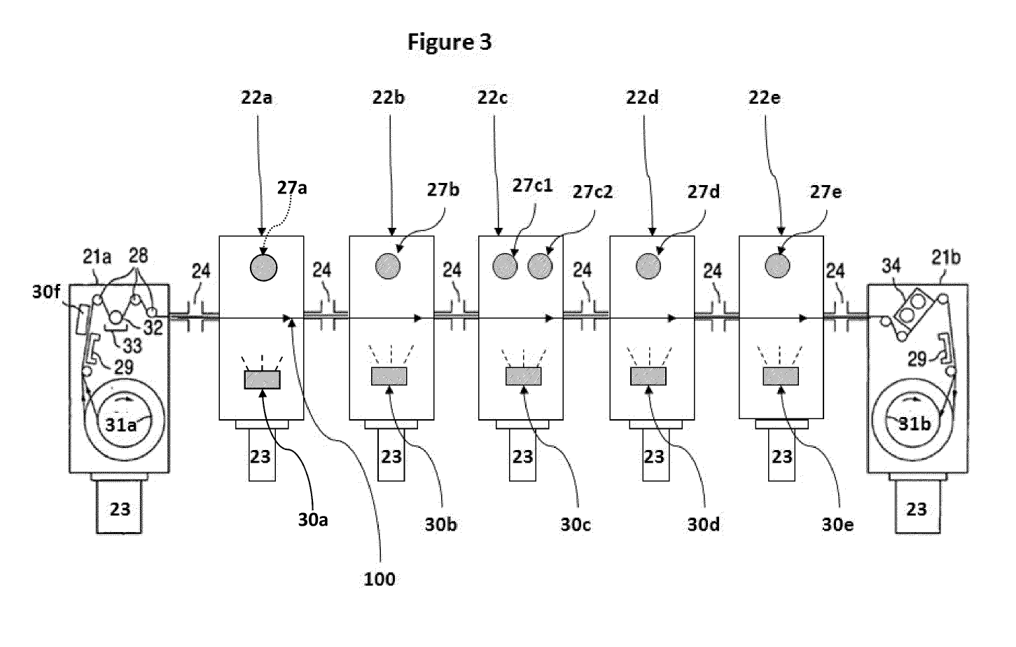

A p-type semiconductor absorber layer 301 comprising sodium doped CIGS, CIGS(Na) is located over the resistive p-type semiconductor layer 500. Layer 301 may have a stoichiometric composition having a Group Ito Group III to Group VI atomic ratio of about 1:1:2, or a non-stoichiometric composition having an atomic ratio of other than about 1:1:2. Preferably, layer 301 is slightly copper deficient and has a slightly less than one copper atom (e.g., 0.8 to 0.99 copper atoms) for each one of Group III atom and each two of Group VI atoms. The step of depositing the at least one p-type semiconductor absorber layer may comprise reactively DC sputtering or reactively AC sputtering the semiconductor absorber layer from at least two electrically conductive targets in a sputtering atmosphere that comprises argon gas and a selenium containing gas (e.g. selenium vapor or hydrogen selenide as described with respect to FIG. 3).

In the first embodiment, the resistivity of the resistive p-type semiconductor layer 500 is greater than the resistivity of the p-type semiconductor absorber layer 301. As such, the resistive p-type semiconductor layer 500 lowers the voltage of the photodiode, thereby rendering the use of a resistive transparent conductive oxide layer for the top electrode optional.

In one aspect of the first embodiment, the hole mobility of the resistive p-type semiconductor layer 500 is lower than the hole mobility of the p-type absorber layer 301, such as 1-100 cm²/V*s. Further, the hole carrier concentration of the resistive p-type semiconductor layer 500 may be equal to or higher than a hole carrier concentration of the p-type absorber layer 301, such as 10¹⁵ to 10¹⁷ cm⁻³. The hole mobility and hole concentration may be determined directly or indirectly by proxy. For example, the relative hole mobility and hole concentration may be determined by measuring and comparing the sodium or gallium concentration in two layers.

The resistive p-type semiconductor layer 500 comprises a semiconductor material that has a lower hole mobility than p-type copper indium gallium selenide of the p-type absorber layer 301 for CIGS absorber based cells. The resistive p-type semiconductor layer 500 and the p-type absorber layer 301 may comprise different materials. For example, the p-type absorber layer 301 may comprise p-CIGS (i.e. slightly Cu deficient CIGS, optionally doped with Na) while the resistive p-type semiconductor layer 500 comprises a p-type semiconductor selected from the group consisting of Si, CuS, ZnSe, CdSe, GaAs and GaP. In an embodiment, the resistive p-type semiconductor layer 500 comprises sodium doped p-type ZnSe and the sodium diffuses from layer 500 into the p-type absorber layer 301 during or after deposition of the p-type absorber layer 301.

Alternatively, both the resistive p-type semiconductor layer 500 and the p-type absorber layer 301 may comprise the same material, e.g., CIGS. The resistive p-type semiconductor layer 500 may be deposited at a lower temperature than the p-type absorber layer 301 to provide at least one of a smaller average grain size or a higher vacancy concentration in the resistive p-type semiconductor layer 500 than in the p-type absorber layer 301 to make the resistive p-type semiconductor layer 500 more resistive and/or have a lower hole mobility than the p-type absorber layer 301.

In an aspect of the first embodiment, the resistive p-type semiconductor layer 500 is capable of sodium diffusion, the first electrode 200 comprises molybdenum which contains sodium and optionally oxygen as discussed above, and the sodium diffuses from the first electrode through the resistive p-type semiconductor layer 500 and optional adhesion layer into the p-type absorber layer during or after deposition of the p-type absorber layer 301. For example, layer 500 may comprise p-CIGS which is deposited at lower temperature than layer 301

An n-type semiconductor layer 302 may then be deposited over the p-type semiconductor absorber layer 301. The n-type semiconductor layer 302 may comprise any suitable n-type semiconductor “window” materials, for example, but not limited to ZnS, ZnSe or CdS.

A second electrode 400, also referred to as a transparent top electrode, is further deposited over the n-type semiconductor layer 302. The transparent top electrode 400 may comprise multiple transparent conductive layers, for example, but not limited to, one or more of an Indium Tin Oxide (ITO), Zinc Oxide (ZnO) or Aluminum Zinc Oxide (AZO) layers 402 located over an optional resistive Aluminum Zinc Oxide (RAZO) layer 401. Of course, the transparent top electrode 400 may comprise any other suitable materials, for example, doped ZnO or SnO. In a preferred embodiment, the second electrode layer 400 does not include the optional resistive Aluminum Zinc Oxide (RAZO) layer 401, since resistive layer 500 already provides sufficient resistance.

Optionally, one or more antireflection (AR) films (not shown) may be deposited over the transparent top electrode 400, to optimize the light absorption in the cell, and/or current collection grid lines may be deposited over the top conducting oxide.

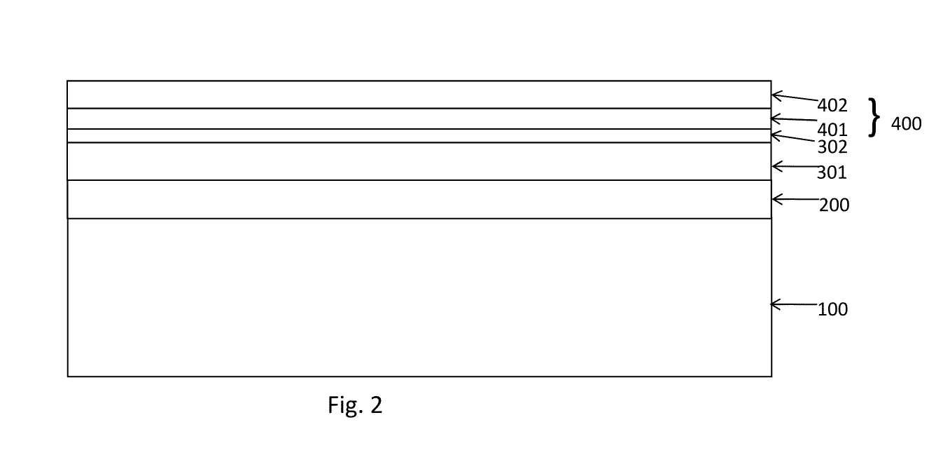

An alternative solar cell embodiment is illustrated in FIG. 2. This second embodiment is similar to the embodiment illustrated in FIG. 1. However, this embodiment does not include the resistive p-type semiconductor layer 500. Rather, in this embodiment, the solar cell is fabricated such that the thickness of the p-type absorber layer 301 is greater than a sum of the depletion width of the diode (formed by the junction of the p-type absorber layer 301 and the n-type semiconductor layer 302) in the p-type absorber layer 301 and a hole diffusion length in the p-type absorber layer 301. The diode is formed at the interface/junction between the p-type absorber layer 301 and the n-type semiconductor layer 302 as holes from the p-type absorber layer 301 diffuse across the interface to the n-type semiconductor layer 302 while electrons from the n-type semiconductor layer 302 diffuse across the interface to the p-type absorber layer 301. This diffusion results in the formation of a contact potential that opposes further diffusion. At equilibrium, the balance between diffusion and the contact potential results in the formation of a region (the depletion region) devoid of mobile charge carriers that extends from the interface/junction into both the p-type absorber layer 301 and the n-type semiconductor layer 302. Because there are no mobile charge carriers in the depletion region, current cannot flow, thus forming the diode. In an aspect of the second embodiment, the p-type absorber layer may comprise p-type copper indium gallium selenide having a thickness greater than 0.7 microns, such as between 0.75 and 3 microns, when the depletion width and the hole diffusion length is 0.6 microns.

Alternatively, the solar cells of the previous embodiments may be formed in reverse order. In this configuration, a transparent electrode 400 is deposited over a substrate 100, followed by depositing an n-type semiconductor layer 302 over the transparent electrode, depositing at least one p-type semiconductor absorber layer 301 over the n-type semiconductor layer 302, and depositing a top electrode 200 comprising a transition metal layer over the at least one p-type semiconductor absorber layer 301. The substrate 100 may be a transparent substrate (e.g., glass) or opaque (e.g., metal). If the substrate 100 used is opaque, then the initial substrate 100 may be delaminated after the steps of depositing the stack of the above described layers, and then bonding a glass or other transparent substrate 100 to the transparent electrode 400 of the stack. The resistive p-type semiconductor layer 500 of the first embodiment may be deposited between the p-type semiconductor absorber layer 301 and the transparent electrode 400.

FIG. 3 illustrates a modular sputtering apparatus that may be used for depositing the layers for making a photovoltaic device. The apparatus is equipped with an input, or load, module 21a and a symmetrical output, or unload, module 21b. Between the input and output modules are process modules 22a, 22c, 22d and 22e. The number of process modules 22 may be varied to match the requirements of the device that is being produced. Each module has a pumping device 23, such as vacuum pump, for example a high throughput turbomolecular pump, to provide the required vacuum and to handle the flow of process gases during the sputtering operation. Each module may have a number of pumps placed at other locations selected to provide optimum pumping of process gases. The modules are connected together at slit valves 24, which contain very narrow low conductance isolation slots to prevent process gases from mixing between modules. These slots may be separately pumped if required to increase the isolation even further. Other module connectors 24 may also be used. Alternatively, a single large chamber may be internally segregated to effectively provide the module regions, if desired. U.S. Published Application No. 2005/0109392 A1 (“Hollars”), filed on Oct. 25, 2004, discloses a vacuum sputtering apparatus having connected modules, and is incorporated herein by reference in its entirety.

The substrate 100 may be a foil web, for example, a metal web substrate, a polymer web substrate, or a polymer coated metal web substrate, and may be continuously passing through the sputtering module 22c during the sputtering process, following the direction of the imaginary arrow along the web 100. Any suitable materials may be used for the foil web. For example, metal (e.g., stainless steel, aluminum, or titanium) or thermally stable polymers (e.g., polyimide or the like) may be used. The foil web 100 may move at a constant or variable rate to enhance deposition.

The web substrate 100 is moved throughout the machine by rollers 28, or other devices. Additional guide rollers may be used. Rollers shown in FIG. 3 are schematic and non-limiting examples. Some rollers may be bowed to spread the web, some may move to provide web steering, some may provide web tension feedback to servo controllers, and others may be mere idlers to run the web in desired positions. The input spool 31a and optional output spool 31b thus are actively driven and controlled by feedback signals to keep the web in constant tension throughout the machine. In addition, the input and output modules may each contain a web splicing region or device 29 where the web 100 can be cut and spliced to a leader or trailer section to facilitate loading and unloading of the roll. In some embodiments, the web 100, instead of being rolled up onto output spool 31b, may be sliced into solar modules or cells by the web splicing device 29 in the output module 21b. In these embodiments, the output spool 31b may be omitted. As a non-limiting example, some of the devices/steps may be omitted or replaced by any other suitable devices/steps. For example, bowed rollers and/or steering rollers may be omitted in some embodiments.

Heater arrays 30 are placed in locations where necessary to provide web heating depending upon process requirements. These heaters 30 may be a matrix of high temperature quartz lamps laid out across the width of the web. Infrared sensors provide a feedback signal to servo the lamp power and provide uniform heating across the web. In one embodiment, as shown in FIG. 3, the heaters are placed on one side of the web 100, and sputtering targets 27 a-e are placed on the other side of the web 100. Sputtering targets 27 may be mounted on dual cylindrical rotary magnetron(s), or planar magnetron(s) sputtering sources, or RF sputtering sources.

After being pre-cleaned, the web substrate 100 may first pass by heater array 30f in module 21a, which provides at least enough heat to remove surface adsorbed water. Subsequently, the web can pass over roller 32, which can be a special roller configured as a cylindrical rotary magnetron. This allows the surface of electrically conducting (metallic) webs to be continuously cleaned by DC, AC, or RF sputtering as it passes around the roller/magnetron. The sputtered web material is caught on shield 33, which is periodically changed. Preferably, another roller/magnetron may be added (not shown) to clean the back surface of the web 100. Direct sputter cleaning of a web 100 will cause the same electrical bias to be present on the web throughout the machine, which, depending on the particular process involved, might be undesirable in other sections of the machine. The biasing can be avoided by sputter cleaning with linear ion guns instead of magnetrons, or the cleaning could be accomplished in a separate smaller machine prior to loading into this large roll coater. Also, a corona glow discharge treatment could be performed at this position without introducing an electrical bias.

Next, the web 100 passes into the process module 22a through valve 24. Following the direction of the imaginary arrows along the web 100, the full stack of layers may be deposited in one continuous process. The first electrode 200 may be sputtered in the process module 22a over the web 100, as illustrated in FIG. 3. Optionally, the process module 22a may include more than one target (e.g., for sputtering barrier and/or adhesion layers).

After depositing the first electrode 200, the web 100 passes into process module 22b through another valve 24. In the process module 22b, the resistive p-type semiconductor layer 500 may be deposited over the first electrode 200. The resistive p-type semiconductor layer 500 may be deposited from a single sputtering target 27b (e.g. CIG target) or from two or more sputtering targets 27b. The resistive p-type semiconductor layer 500 may be deposited in a Se atmosphere by reactive DC sputtering or reactive alternating current (AC) magnetron sputtering in a Se atmosphere (e.g., evaporated Se). The resistive p-type semiconductor layer may comprise a phase separated p-type semiconductor material (that is, a semiconductor material that self-segregates into two phases having different compositions and/or crystal structures) or a laminate of plural p-type semiconductor material layers. Further, both the resistive p-type semiconductor layer 500 and the p-type absorber layer 301 may comprise the same material, e.g., CIGS. The resistive p-type semiconductor layer 500 may be deposited at a lower temperature than the p-type absorber layer 301 to provide at least one of a smaller average grain size or a higher vacancy concentration in the resistive p-type semiconductor layer 500 than in the p-type absorber layer 301 to make the resistive p-type semiconductor layer 500 more resistive than the p-type absorber layer 301. This may be accomplished, for example, by depositing at a lower temperature in process module 22b than in process module 22c (discussed below).

One or more targets (e.g., targets 27c1 and 27c2) are located in a sputtering process module 22c, such as a vacuum chamber. While one or two targets are shown in the modules 22 illustrated in FIGS. 3, 1 to 8 targets may be used. In this non-limiting example, the targets, e.g. targets 27c1 and 27c2, are powered by DC power sources 7. A CIGS layer 301 may be deposited over a substrate 100, such as a moving web substrate, by reactively sputtering the layer from targets 27c1, 27c2 in an atmosphere that comprises a sputtering gas (e.g., argon gas) and a selenium-containing gas, such as evaporated selenium or hydrogen selenide gas. Alternatively, the sputtering may comprise reactively alternating current (AC) magnetron sputtering the p-type absorber layer 301 from at least one pair of two conductive targets 27c1 and 27c2, in a sputtering atmosphere that comprises argon gas and a selenium-containing gas. In some embodiments, the conductive targets 27c1 and 27c2 comprise the same target materials. In an alternative embodiment, if layers 500 and 301 both comprise CIGS, then process module 22b can be eliminated. Process module 22c may be configured for depositing both the resistive p-type semiconductor layer 500 and the p-type absorber layer 301. The first target 27c1 (or set of targets) may be used for depositing the resistive p-type semiconductor layer 500 and the second target 27c1 (set of targets) used for depositing the p-type absorber layer 301. The temperature at the front of process module 22c, near target 27c1 may be lower than the temperature in the back or process module 22c, near target 27c2. However, separate process modules 22a, 22b may be preferred if the resistive p-type semiconductor layer 500 and the p-type absorber layer 301 are different materials rather than merely having different resistivity and/or hole mobility.

Alternatively, as noted above, the p-type semiconductor layer 500 may comprise sodium doped ZnSe. Sodium from the sodium doped p-type semiconductor layer 500 can be diffused into the p-type absorber layer 301 during deposition of the p-type absorber layer 301 or during a heating step which occurs after deposition of the p-type absorber layer 301. Alternatively, the resistive p-type semiconductor layer 500 may be capable of sodium diffusion. In this embodiment, the first electrode 200 may comprise molybdenum which contains sodium and the sodium diffuses from the first electrode 200 through the resistive p-type semiconductor layer 500 into the p-type absorber layer 301 during deposition of the p-type absorber layer 301 or during a heating step which occurs after deposition of the p-type absorber layer 301.

The web 100 may then pass into the process modules 22d and 22e, for depositing the n-type semiconductor layer 302, and the transparent top electrode 400, respectively. Any suitable type of sputtering sources may be used, for example, rotating AC magnetrons, RF magnetrons, or planar magnetrons. Extra magnetron stations (not shown), or extra process modules (not shown) could be added for sputtering the optional one or more anti-reflection (AR) layers.

Finally, the web 100 passes into output module 21b, where it is either wound onto the take up spool 31b, or sliced into solar cells using cutting apparatus 29. While sputtering was described as the preferred method for depositing all layers onto the substrate, some layers may be deposited by MBE, CVD, evaporation, plating, etc., while, preferably, the CIS based alloy is reactively sputtered.

Although the foregoing refers to particular preferred embodiments, it will be understood that the invention is not so limited. It will occur to those of ordinary skill in the art that various modifications may be made to the disclosed embodiments and that such modifications are intended to be within the scope of the invention. All of the publications, patent applications and patents cited herein are incorporated herein by reference in their entirety.

What is claimed is:

1. A photovoltaic device, comprising:
a substrate;
a first electrode layer over the substrate;
a resistive p-type semiconductor layer over the first electrode layer;
a p-type absorber layer over the resistive p-type semiconductor layer;
an n-type semiconductor layer over the p-type absorber layer; and
a second electrode layer over the n-type semiconductor layer;
wherein a resistivity of the resistive p-type semiconductor layer is greater than a resistivity of the p-type absorber layer.

2. The device of claim 1, wherein a hole mobility of the resistive p-type semiconductor layer is lower than a hole mobility of the p-type absorber layer.

3. The device of claim 2, wherein a hole carrier concentration of the resistive p-type semiconductor layer is equal to or higher than a hole carrier concentration of the p-type absorber layer.

4. The device of claim 2, wherein the resistive p-type semiconductor layer has at least one of a smaller average grain size or a higher vacancy concentration than the p-type absorber layer.

5. The device of claim 4, wherein the resistive p-type semiconductor layer comprises copper indium gallium selenide, and the p-type absorber layer comprises copper indium gallium selenide.

6. The device of claim 2, wherein the resistive p-type semiconductor layer comprises a semiconductor material which has a lower hole mobility than p-type copper indium gallium selenide, and the p-type absorber layer comprises p-type copper indium gallium selenide.

7. The device of claim 6, wherein the resistive p-type semiconductor layer comprises a p-type semiconductor selected from the group consisting of Si, CuS, ZnSe, CdSe, GaAs and GaP.

8. The device of claim 7, wherein the p-type semiconductor layer comprises sodium doped ZnSe and wherein the sodium diffuses into the p-type absorber layer during or after deposition of the p-type absorber layer.

9. The device of claim 2, wherein the resistive p-type semiconductor layer comprises a phase separated p-type semiconductor material or a laminate of plural p-type semiconductor material layers.

10. The device of claim 1, wherein the resistive p-type semiconductor layer is capable of sodium diffusion, the first electrode comprises molybdenum which contains sodium, and the sodium diffuses from the first electrode through the resistive p-type semiconductor layer into the p-type absorber layer during or after deposition of the p-type absorber layer.

11. The device of claim 1, wherein the n-type semiconductor layer comprises n-CdS and the second electrode layer comprises a first transparent layer comprising Indium Tin Oxide (ITO), Zinc Oxide (ZnO) or Aluminum Zinc Oxide (AZO) over a second transparent layer comprising resistive Aluminum Zinc Oxide (RAZO).

12. A photovoltaic device, comprising:
a substrate;
a first electrode layer over the substrate;
a p-type absorber layer over the resistive p-type semiconductor layer;
an n-type semiconductor layer over the p-type absorber layer; and
a second electrode layer over the n-type semiconductor layer,
wherein the junction of the p-type absorber layer and the n-type semiconductor layer form a diode and a thickness of the p-type absorber layer is greater than a sum of a depletion width of the diode in the p-type absorber layer and a hole diffusion length in the p-type absorber layer.

13. The device of claim 12, wherein the p-type absorber layer comprises copper indium gallium selenide having a thickness greater than 0.7 microns.

14. A method of making a photovoltaic device, comprising:
depositing a first electrode layer over a substrate;
depositing a resistive p-type semiconductor layer over the first electrode layer;
depositing a p-type absorber layer over the resistive p-type semiconductor layer;
depositing an n-type semiconductor layer over the p-type absorber layer; and
depositing a second electrode layer over the n-type semiconductor layer;
wherein a resistivity of the resistive p-type semiconductor layer is greater than a resistivity of the p-type absorber layer.

15. The method of claim 14, wherein a hole mobility of the resistive p-type semiconductor layer is lower than a hole mobility of the p-type absorber layer.

16. The method of claim 15, wherein a hole carrier concentration of the resistive p-type semiconductor layer is equal to or higher than a hole carrier concentration of the p-type absorber layer.

17. The method of claim 15, wherein the resistive p-type semiconductor layer is deposited at a lower temperature than the p-type absorber layer to provide at least one of a smaller average grain size or a higher vacancy concentration in the resistive p-type semiconductor layer than in the p-type absorber layer.

18. The method of claim 17, wherein the resistive p-type semiconductor layer comprises copper indium gallium selenide, and the p-type absorber layer comprises copper indium gallium selenide.

19. The method of claim 15, wherein the resistive p-type semiconductor layer comprises a semiconductor material which has a lower hole mobility than p-type copper indium gallium selenide, and the p-type absorber layer comprises p-type copper indium gallium selenide.

20. The method of claim 19, wherein the resistive p-type semiconductor layer comprises a p-type semiconductor selected from the group consisting of Si, CuS, ZnSe, CdSe, GaAs and GaP.

21. The method of claim 20, wherein the p-type semiconductor layer comprises sodium doped ZnSe and wherein the sodium diffuses into the p-type absorber layer during deposition of the p-type absorber layer or during a heating step which occurs after deposition of the p-type absorber layer.

22. The method of claim 15, wherein the resistive p-type semiconductor layer comprises a phase separated p-type semiconductor material or a laminate of plural p-type semiconductor material layers.

23. The method of claim 14, wherein the resistive p-type semiconductor layer is capable of sodium diffusion, the first electrode comprises molybdenum which contains sodium, and the sodium diffuses from the first electrode through the resistive p-type semiconductor layer into the p-type absorber layer during deposition of the p-type absorber layer or during a heating step which occurs after deposition of the p-type absorber layer.

24. The method of claim 14, wherein the n-type semiconductor layer comprises n-CdS; and
wherein depositing the second electrode layer further comprises:
depositing a first transparent layer comprising resistive Aluminum Zinc Oxide (RAZO); and
depositing a second transparent layer comprising Indium Tin Oxide (ITO), Zinc Oxide (ZnO) or Aluminum Zinc Oxide (AZO) over the RAZO layer.

25. A method of operating a photovoltaic device, comprising:
a substrate;
a first electrode layer over the substrate;
a p-type absorber layer over the resistive p-type semiconductor layer;
an n-type semiconductor layer over the p-type absorber layer; and
a second electrode layer over the n-type semiconductor layer,
wherein the method comprises applying a current or voltage to the first and the second electrode layers such that a junction of the p-type absorber layer and the n-type semiconductor layer form a diode with a depletion region which partially extends from the junction into the p-type absorber layer to a depth which differs from the thickness of the p-type absorber layer by at least a hole diffusion length in the p-type absorber layer.

26. The method of claim 25, wherein the p-type absorber layer comprises copper indium gallium selenide having a thickness greater than 0.7 microns.
